(19) United States
(12) Patent Application Publication
(10) Pub. No.: US 2009/0060018 A1
(43) Pub. Date: Mar. 5, 2009

(54) Transmit Equalizer For Dispersive Channels

(75) Inventors: Oscar E. Agazzi, Irvine, CA (US); Hugo S. Carrer, Cordoba (AR)

Correspondence Address: FENWICK & WEST LLP, SILICON VALLEY CENTER, 801 CALIFORNIA STREET, MOUNTAIN VIEW, CA, 94041, US

(73) Assignee: ClariPhy Communications, Inc., Irvine, CA (US)

(21) Appl. No.: 12/056,229

(22) Filed: Mar. 26, 2008

Related U.S. Application Data
(60) Provisional application No. 60/908,151, filed on Mar. 26, 2007.

(51) Int. Cl. H03H 7/30

(52) U.S. Cl. 375/230

(57) ABSTRACT

An equalizer at the transmitter reduces data-dependent jitter introduced by a non-linear device in the transmitter. In one implementation, the equalizer is T/2-spaced. In an alternate implementation, it is T-spaced.

### CROSS-REFERENCE TO RELATED APPLICATION(S)

This application claims priority under 35 U.S.C. § 119(e) to U.S. Provisional Patent Application Ser. No. 60/908,151, “Transmit Equalizer for Dispersive Channels,” filed Mar. 26, 2007 by Oscar E. Agazzi and Hugo S. Carrer. The subject matter of the foregoing is incorporated herein by reference in its entirety.

### BACKGROUND OF THE INVENTION

1. Field of the Invention

This invention relates generally to transmitters and transceivers used for data transmission on high-speed communication channels with intersymbol interference (ISI) and, more specifically, to equalizers used to compensate the ISI and/or data-dependent jitter (DDJ) by prefiltering the signal at the transmitter.

2. Description of the Related Art

In some communication channels, the transmitted signal is processed by a nonlinear element after having propagated through part of the channel. Except for this nonlinear element, the channel is substantially linear, but it may be dispersive. In these situations, the nonlinear element may transform the ISI generated by the linear part of the channel that precedes it into DDJ. DDJ cannot be easily compensated by the receiver at the other end of the channel. Therefore, it is desirable to minimize the amount of DDJ generated by the nonlinear element.

### SUMMARY OF THE INVENTION

The present invention overcomes the limitations of the prior art by providing an equalizer at the transmitter. In one implementation, the equalizer is T/2-spaced. In an alternate implementation, it is T-spaced.

Other aspects of the invention include systems that use these devices, and methods corresponding to the devices and systems described above.

### BRIEF DESCRIPTION OF THE DRAWINGS

The invention has other advantages and features which will be more readily apparent from the following detailed description of the invention and the appended claims, when taken in conjunction with the accompanying drawings, in which:

FIG. 1 shows a model used to analyze data dependent jitter (DDJ).

FIGS. 2a and 2b show corresponding eye patterns at the input and at the output of the slicer of FIG. 1.

FIG. 3 shows a block diagram of an example T/2-spaced equalizer.

FIGS. 4a and 4b show corresponding eye patterns at the input and at the output of the slicer for a 20 tap T/2 equalizer.

FIG. 5 shows the coefficients of the 20 tap T/2 equalizer.

FIGS. 6a and 6b show corresponding eye patterns at the input and at the output of the slicer for a 10 tap equalizer.

FIG. 7 is a model of a channel suitable for use with the invention.

FIG. 8 graphs DDJ as a function of the DAC resolution for T/2- and T-spaced equalizers.

FIG. 9 graphs DDJ as a function of tap threshold for T/2- and T-spaced equalizers.

FIG. 10 graphs the number of surviving taps as a function of tap threshold for T/2- and T-spaced equalizers.

FIG. 11 graphs DDJ as a function of the number of taps for T/2- and T-spaced equalizers.

FIG. 12 shows the eye pattern at the SERDES output.

FIGS. 13a and 13b shows eye patterns at the input pad of the laser driver, without and with equalizer.

FIGS. 14a and 14b shows eye patterns at the input of the laser driver, without and with equalizer.

FIGS. 15a and 15b shows eye patterns at the output of the laser, without and with equalizer.

The figures depict embodiments of the present invention for purposes of illustration only. One skilled in the art will readily recognize from the following discussion that alternative embodiments of the structures and methods illustrated herein may be employed without departing from the principles of the invention described herein.

### DETAILED DESCRIPTION OF THE PREFERRED EMBODIMENTS

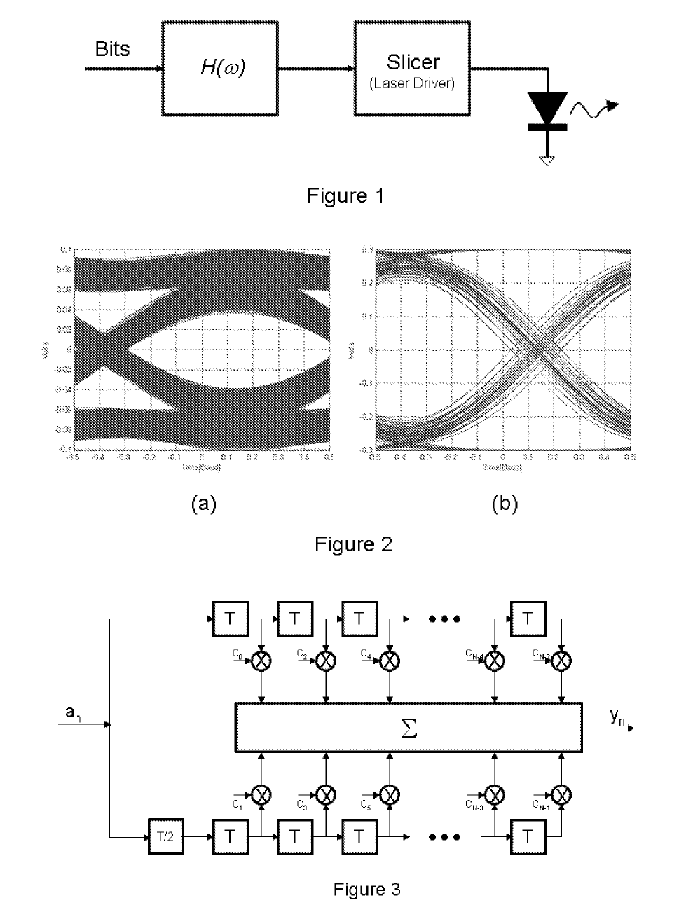

The problem of equalizing the signal to minimize DDJ is somewhat different from the problem of minimizing ISI. This can be seen as follows. FIG. 1 shows a model used to analyze data dependent jitter (DDJ). The linear portion of the channel is modeled by transfer function H(ω) and the non-linear element in this example is a slicer (e.g., a laser driver). The non-linear element transforms the ISI generated by the linear part of the channel that precedes it into DDJ. FIG. 2a shows a possible eye pattern at the input of the slicer of FIG. 1, and FIG. 2b shows the corresponding eye pattern at the output of the slicer. Notice that a nonzero rise time is assumed at the output of the slicer.

An example of a channel where the aforementioned effect occurs and may need to be compensated is an electrical-optical channel as described in the SFF-8431 Specification for Enhanced 8.5 and 10 Gigabit Small Form Factor Pluggable “SFP+” document. The nonlinear element in this channel is the combination of the laser driver and the laser.

DDJ is caused by the oscillations of the zero crossings of the signal at the input of the slicer. To minimize DDJ, the phase of these zero crossings must be accurately controlled. Now consider the condition that the response H(ω) preferably should meet to achieve zero DDJ.

### I. Condition for Zero DDJ and Zero ISI

For notational convenience, in these examples, assume that the pulse h(t) is noncausal, and the sampling phase that corresponds to maximum eye opening is t=nT, where T=1/f_{B} is the baud period, f_{B} is the baud rate, and n is an integer. Also assume that the instants of the zero crossings are t=T/2+mT, where m is another integer. To identify the condition for zero DDJ, first prove several theorems.

Theorem 1:

If the Fourier transform F(ω) of a pulse f(t) satisfies condition:

$${\sum }_{k = - ∞}^{∞} {( - 1 )}^{k} F ( ω - \frac{2 k π}{T} ) = 0 \qquad ( 1 )$$

then f(t) is a zero DDJ pulse of the form:

$$f ( t ) = g ( t ) cos ( \frac{π t}{T} ) \qquad ( 2 )$$

Proof:

Define:

$${F}_{A} ( ω ) = {\sum }_{k = - ∞}^{∞} F ( ω - \frac{4 k π}{T} ) \qquad ( 3 )$$

and

$${F}_{B} ( ω ) = {\sum }_{k = - ∞}^{∞} F ( ω - \frac{2 π ( 2 k + 1 )}{T} ) \qquad ( 4 )$$

Then equation (1) can be rewritten as:

F_{A}(ω)=F_{B}(ω) (5)

We also observe that:

$${F}_{B} ( ω ) = {F}_{A} ( ω - \frac{2 π}{T} ) \qquad ( 6 )$$

Finally, condition (1) can be written as:

$${F}_{A} ( ω ) = {F}_{A} ( ω - \frac{2 π}{T} ) \qquad ( 7 )$$

Notice that F_{A}(ω) is the Fourier transform of f(t) sampled at the rate 2f_{B}. Equation (7) states that F_{A}(ω) is a periodic function with period

$$\frac{2 π}{T} .$$

Observe that, based on sampling considerations alone, we would expect the period of F_{A}(ω) to be twice as large, or

$$\frac{4 π}{T} .$$

This periodicity condition can be satisfied if and only if F(ω) is of the form:

$$F ( ω ) = \frac{1}{2} G ( ω - \frac{π}{T} ) + \frac{1}{2} G ( ω + \frac{π}{T} ) \qquad ( 8 )$$

This means that f(t) must be of the form:

$$f ( t ) = g ( t ) cos ( \frac{π t}{T} ) \qquad ( 9 )$$

Clearly, this pulse has zero crossings at

$$t = \frac{T}{2} + mT .$$

This means it is zero DDJ pulse.

Theorem 2:

A pulse h(t) has zero DDJ if and only if its Fourier transform H(ω) satisfies the condition:

$${\sum }_{k = - ∞}^{∞} {( - 1 )}^{k} H ( ω - \frac{2 π k}{T} ) = 2 K cos ( \frac{ω T}{2} ) \qquad ( 10 )$$

where

$$K = h ( \frac{T}{2} ) = h ( - \frac{T}{2} )$$

(notice that K could be zero, as in pulse (9)).

Proof:

It is easy to see that h(t) has zero DDJ if and only if:

$$h ( nT - \frac{T}{2} ) = K {δ}_{- 1 , n} + K {δ}_{1 , n} \qquad ( 11 )$$

Applying the discrete Fourier transform to both sides of (11) we get (10).

Theorem 3:

A pulse h(t) has zero DDJ if and only if it is of the form:

$$h ( t ) = g ( t ) cos ( \frac{π t}{T} ) + Kp ( t - \frac{T}{2} ) + Kq ( t + \frac{T}{2} ) \qquad ( 12 )$$

where p(t) and q(t) are pulses that satisfy the Nyquist condition for signaling with zero ISI at the rate 1/T.

Proof:

If h(t) satisfies condition (12), it obviously has zero DDJ. To prove the converse, assume P(ω) and Q(ω) are the Fourier transforms of p(t) and q(t), respectively. Then, using Theorem 2 it is easy to see that:

F(ω)=H(ω)−KP(ω)−KQ(ω) (13)

satisfies condition (1). From the inverse Fourier transform of (13) and Theorem 1, equation (12) follows.

It is possible to create pulses of the form (12) with very small excess bandwidth. However, pulses with small excess bandwidth will cause large ISI at the center of the eye pattern. If we also want to ensure zero ISI, h(t) must satisfy an additional condition. To identify this condition, we prove the following theorem.

Theorem 4:

To have both zero DDJ and zero ISI, pulse h(t) must have at least 100% excess bandwidth.

Proof:

According to Theorem 2, to achieve zero DDJ H(ω) must meet condition (10):

$${\sum }_{k = - ∞}^{∞} {( - 1 )}^{k} H ( ω - \frac{2 π k}{T} ) = 2 K cos ( \frac{ω T}{2} )$$

Also, to achieve zero ISI H(ω) must satisfy the Nyquist condition:

$${\sum }_{k = - ∞}^{∞} H ( ω - \frac{2 π k}{T} ) = 1 \qquad ( 14 )$$

Adding the two equations, we get:

$${\sum }_{k = - ∞}^{∞} H ( ω - \frac{4 π k}{T} ) = 1 + 2 K cos ( \frac{ω T}{2} ) \qquad ( 15 )$$

Since the right hand side of (15) is nonzero (with the possible exception of some isolated points), H(ω) must have at least 100% bandwidth. This proves the theorem.

### Example

A 100% raised cosine pulse

$$h ( t ) = ( \frac{sin ( π t \text{/} T )}{( π t \text{/} T )} ) ( \frac{cos ( π t \text{/} T )}{1 - {( 2 t \text{/} T )}^{2}} ) \qquad ( 16 )$$

satisfies the conditions of Theorems 3 and 4. It is well known that this pulse has zero ISI, so we only need to show that it also has zero DDJ. To see this, we write:

$$\frac{1}{1 - {( 2 t \text{/} T )}^{2}} = \frac{T \text{/} 4}{( t + \frac{T}{2} )} - \frac{T \text{/} 4}{( t - \frac{T}{2} )} \qquad ( 17 )$$

Then, using the trigonometric identities:

$$cos ( \frac{π t}{T} ) = sin \frac{π}{T} ( t + \frac{T}{2} ) = - sin \frac{π}{T} ( t - \frac{T}{2} ) \qquad ( 18 )$$

we can rewrite (16) as:

$$h ( t ) = \frac{π}{4} ( \frac{sin ( π t \text{/} T )}{( π t \text{/} T )} ) ( \frac{sin \frac{π}{T} ( t - \frac{T}{2} )}{\frac{π}{T} ( t - \frac{T}{2} )} + \frac{sin \frac{π}{T} ( t + \frac{T}{2} )}{\frac{π}{T} ( t + \frac{T}{2} )} ) \qquad ( 19 )$$

This is a pulse of the form (12), with g(t)=0, K=½, and:

$$\begin{matrix}p ( t ) = \frac{π}{2} ( \frac{sin ( π t \text{/} T )}{( π t \text{/} T )} ) ( \frac{sin \frac{π}{T} ( t + \frac{T}{2} )}{\frac{π}{T} ( t + \frac{T}{2} )} ) & ( 20 ) \\ q ( t ) = \frac{π}{2} ( \frac{sin ( π t \text{/} T )}{( π t \text{/} T )} ) ( \frac{sin \frac{π}{T} ( t - \frac{T}{2} )}{\frac{π}{T} ( t - \frac{T}{2} )} ) & ( 21 )\end{matrix}$$

Therefore, from Theorem 3 we conclude that a 100% excess bandwidth raised cosine pulse has zero DDJ.

### II. Equalization of DDJ

To meet the condition of Theorem 4, the signal is shaped over a bandwidth of 2π/T which generally requires a fractionally spaced equalizer with a maximum tap spacing of T/2. The coefficients can be computed by solving the minimum mean squared error (MMSE) equations. The DSP implementation of this equalizer is relatively simple because the input is a data sequence. Therefore no multipliers are required. Also, the filter lends itself well to a polyphase structure implementation. Often, a high-speed DAC is required at the output. The bandwidth should be large enough that no significant degradation is introduced within the signal bandwidth. FIG. 3 shows a block diagram of an example equalizer.

Such an equalizer could be implemented using a lookup table based parallel architecture similar to the one used for the FFE in the receiver. One difference would be that the input signal has a resolution of only 1 bit, which significantly reduces the number of lookup tables needed and the size of the adder tree at the output. Another difference is that the filter is not adaptive but programmable.

### III. T/2-Spaced Equalizer Simulations

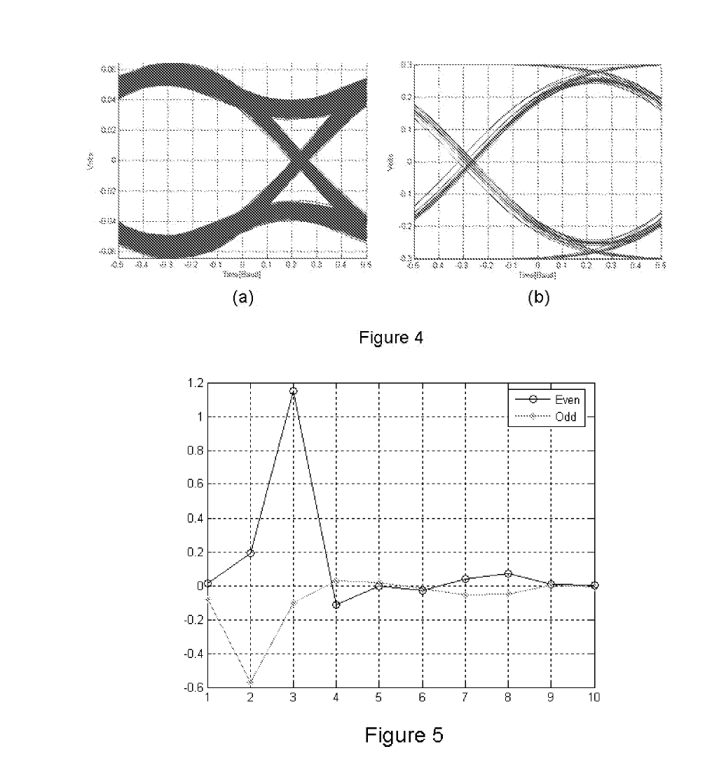

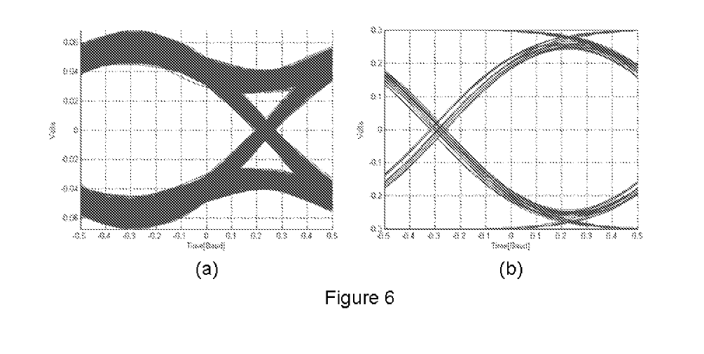

The performance of such an equalizer was simulated (ignoring implementation limitations) using the line card model described by H. S. Carrer. FIG. 4a shows the eye pattern at the input of the slicer for a 20 tap T/2 equalizer, and FIG. 4b shows the eye pattern at the output of the slicer. FIG. 5 shows the coefficients of the equalizer. FIGS. 6a and 6b show the eye patterns for a 10 tap equalizer.

### IV. T-spaced Equalizer

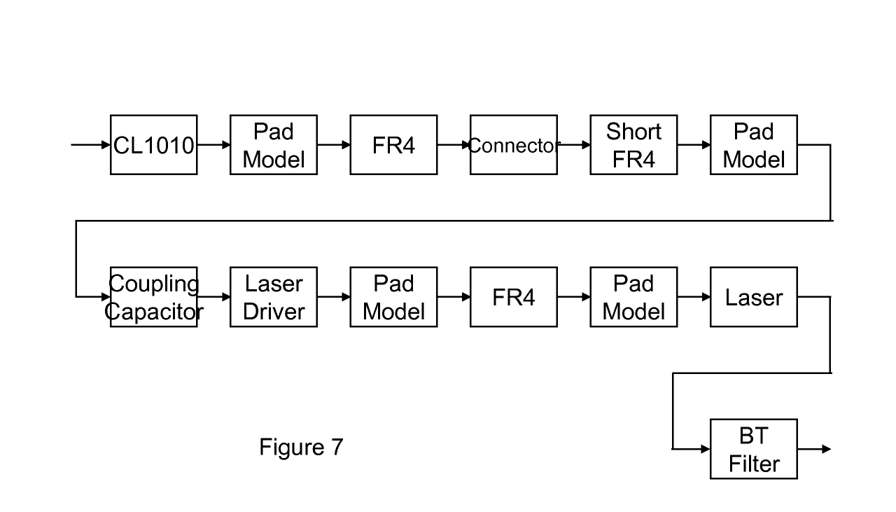

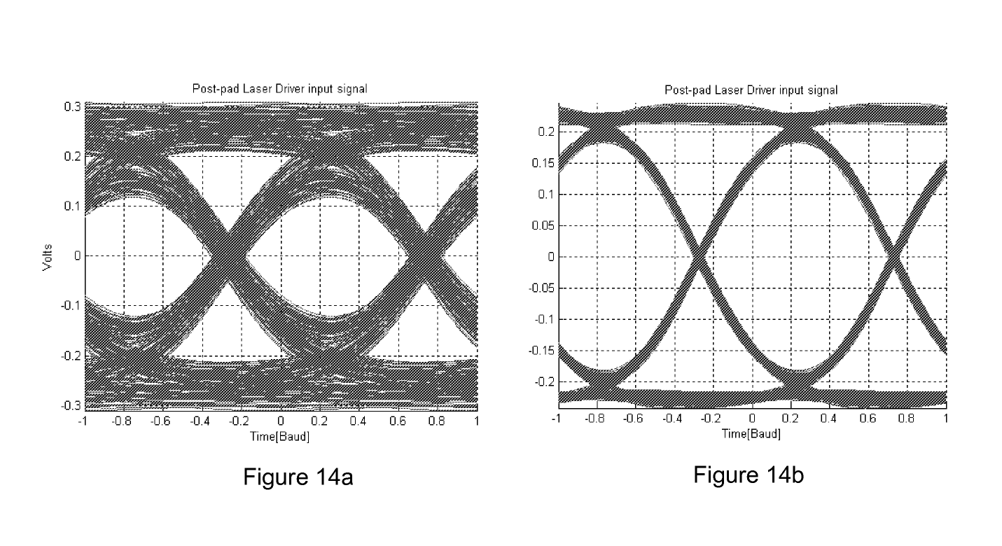

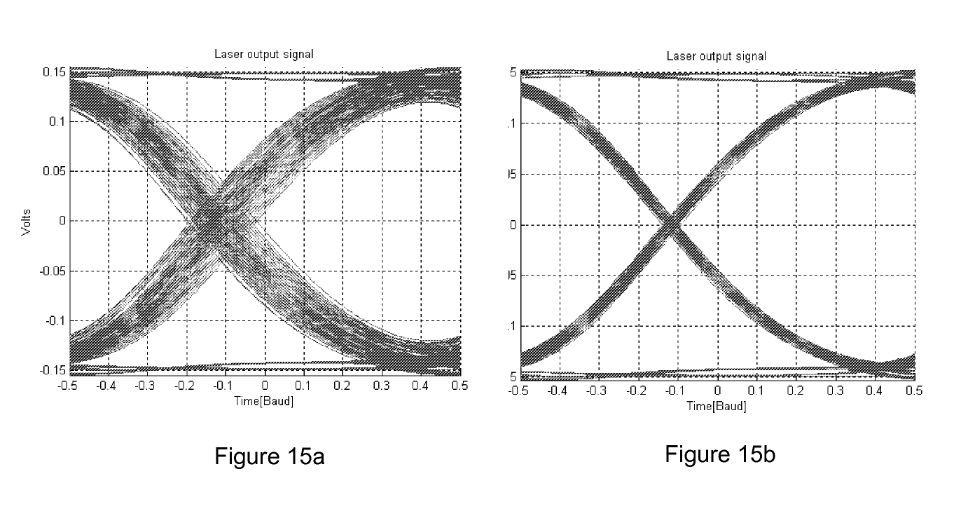

Above, it is shown that a preferred embodiment of an equalizer designed to minimize DDJ is a fractionally-spaced FIR equalizer. However, for reasons of simplicity of implementation, a symbol-spaced (or “T-spaced”) equalizer may be preferable in certain cases. FIGS. 7-15 describe examples of T-spaced equalizers. In this example, the FIR filter includes three groups of taps, besides the main tap:
Precursor taps: This group of taps is located at positions (immediately) preceding the main tap.
Postcursor taps: This group of taps is located at positions (immediately) following the main tap.
Delayed postcursor taps: This group of taps is located at positions following Group 2 (the postcursor taps), and delayed by a programmable number of symbol periods.
   In one design, the filter is implemented by a set of digitally programmable current sources.

The coefficients of the filter are computed by an algorithm that minimizes DDJ at the input of the LDD. For the T-spaced embodiment, the coefficients that minimize ISI do not necessarily minimize DDJ. The well-known minimum mean squared error (MMSE) solution for the linear equalizer minimizes ISI and not DDJ. However, the MMSE solution is a good starting point for an iterative optimization algorithm that minimizes DDJ. This algorithm can be based in any of the well-known nonlinear optimization algorithms, stochastic optimization algorithms, or it can be based on an exhaustive search.

Apart from finding the optimum value of the coefficients from the DDJ point of view, the optimization algorithms are also capable of finding the optimum filter configuration. For the preferred embodiment, this means finding the best delay value for the coefficients of Group 3.

By changing the target of the optimization algorithm this same filter can be used to generate special test waveforms for various purposes. The filter coefficients can be computed to give such a response that the waveform at the output of a given linear channel has some desired characteristics (e.g., to emulate the LRM stressors, produce a particular TWDP value, or give certain time varying characteristics).

FIG. 7 is a model of a channel with the effects described above. This model can be used to model the SFF-8431 channel, for example. The laser driver and laser are the non-linear element that transforms ISI to DJJ.

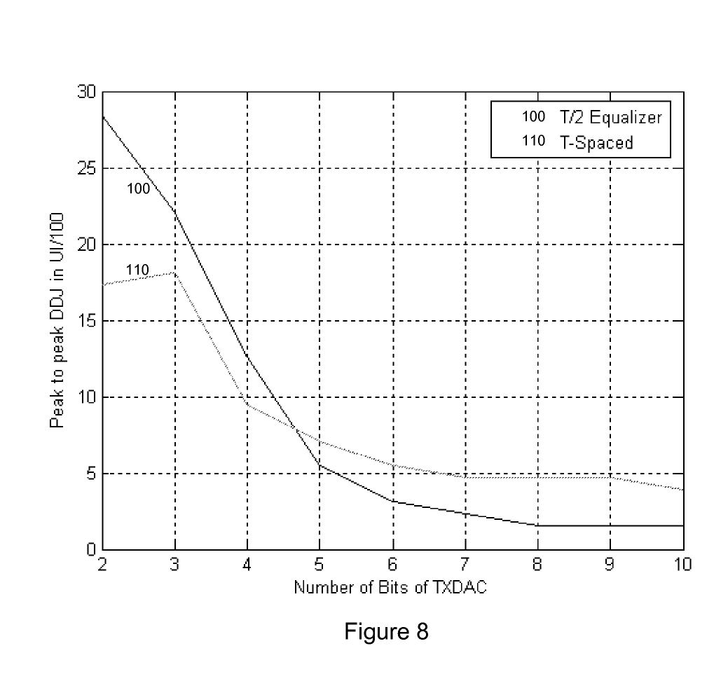

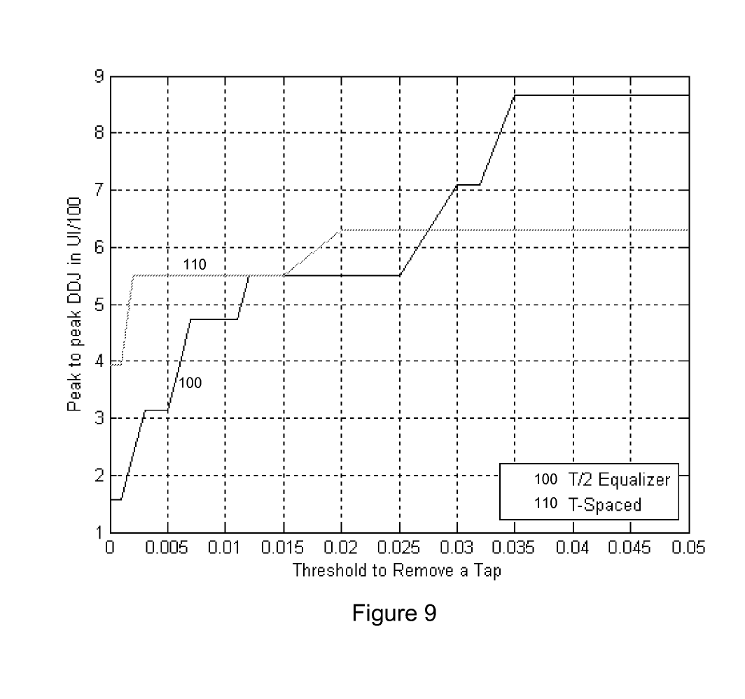

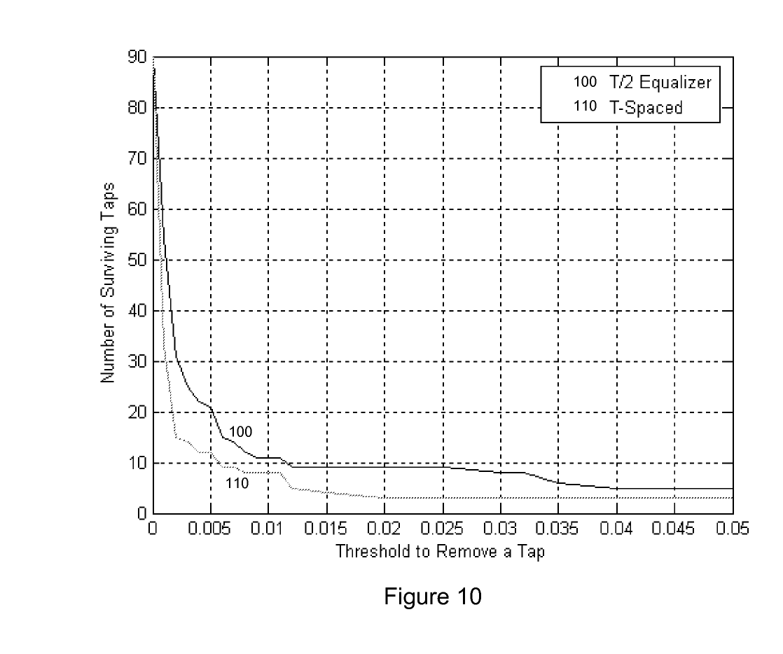

FIGS. 8-11 show various parametric studies of the performance of such an equalizer. FIG. 8 graphs DDJ as a function of the DAC resolution. FIG. 9 graphs DDJ as a function of tap threshold. FIG. 10 graphs the number of surviving taps as a function of tap threshold. In all these figures, curve 100 is for the T/2-spaced equalizer while curve 110 is for the T-spaced equalizer.

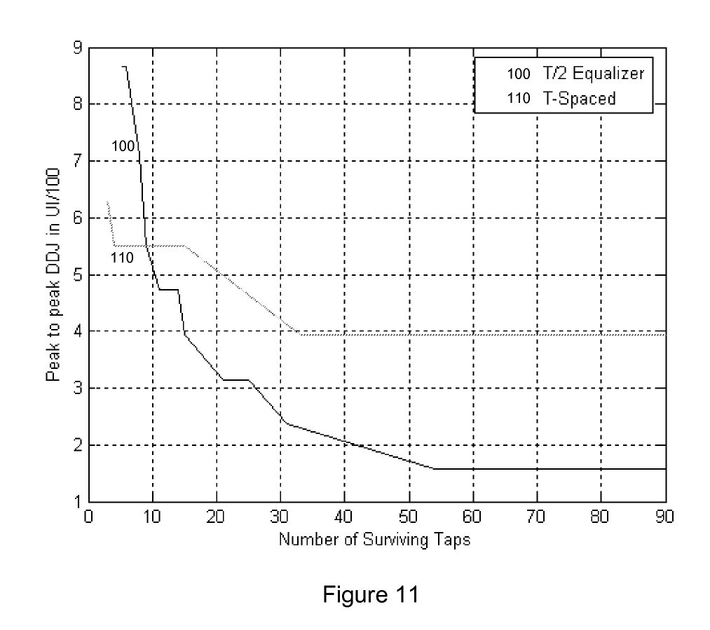

FIG. 11 graphs DDJ as a function of the number of taps. Note that the T-spaced equalizer performs better at lower numbers of taps. The T/2-spaced equalizer performs better at higher numbers of taps. Generally speaking, a T/2 equalizer can reduce DDJ to a lower value than a T-spaced equalizer. However, to fully realize the advantage of the T/2 architecture, a large number of taps is usually required. For moderate to low number of taps, a T-spaced equalizer is preferable. In this particular example, the cross-over point is at approximately 10 taps.

### V. T-spaced Equalizer Simulations

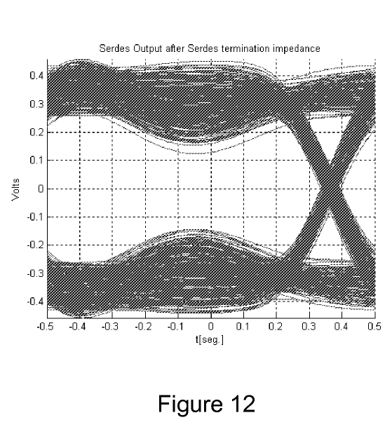

FIGS. 12-15 show the results of simulations for a T-spaced equalizer. The following simulations have been done with a T-spaced equalizer with a total of 10 taps, divided into two groups of 7 and 3 taps respectively. The first group equalizes the main part of the received pulse, and the second group equalizes the reflection coming from the far-end. It is assumed that the implementation is based on digitally programmable current sources, where the “large” tap values are provided by 8-bit DACs, and the “small” tap values are provided by 5-bit DACs.

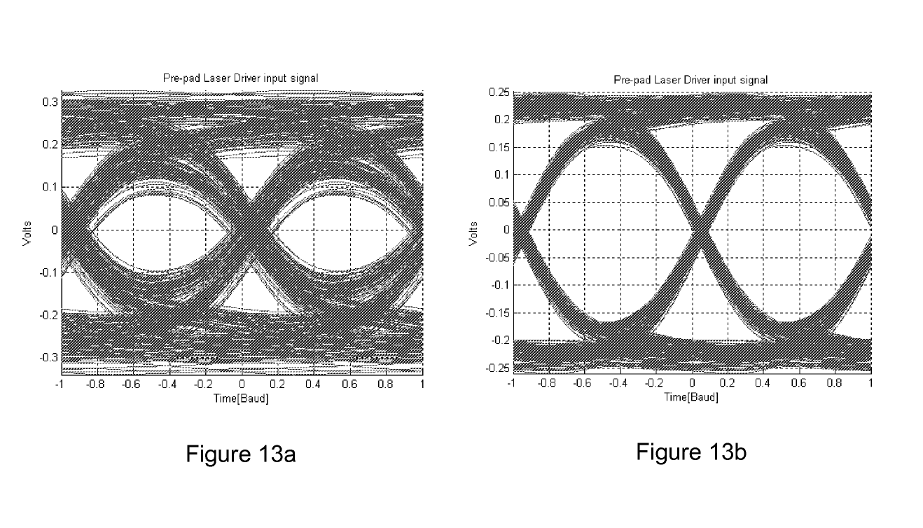

FIG. 12 shows the eye pattern at the SERDES output. FIGS. 13, 14 and 15 show the corresponding eye patterns at the input pad of the laser driver, at the input of the laser driver, and at the output of the laser (assuming a Gaussian laser with 20 ps rise time), respectively. In each of FIGS. 13-15, (a) shows the eye pattern without the equalizer and (b) shows the eye pattern with the equalizer to allow a direct comparison.

Although the detailed description contains many specifics, these should not be construed as limiting the scope of the invention but merely as illustrating different examples and aspects of the invention. It should be appreciated that the scope of the invention includes other embodiments not discussed in detail above. Various other modifications, changes and variations which will be apparent to those skilled in the art may be made in the arrangement, operation and details of the method and apparatus of the present invention disclosed herein without departing from the spirit and scope of the invention as defined in the appended claims. Therefore, the scope of the invention should be determined by the appended claims and their legal equivalents.

What is claimed is:

1. A transmitter equalizer that reduces data-dependent jitter introduced by a non-linear device in the transmitter.
